(19) United States
(12) Patent Application Publication
(10) Pub. No.: US 2014/0172343 A1
(43) Pub. Date: Jun. 19, 2014

(54) Emulation System and Method

(71) Applicant: INFINEON TECHNOLOGIES AG, Neubiberg (DE)

(72) Inventors: Georg Pelz, Ebersberg (DE); Manuel Harrant, Oberhaching (DE); Thomas Nirmaier, Muenchen (DE)

(73) Assignee: INFINEON TECHNOLOGIES AG, Neubiberg (DE)

(21) Appl. No.: 13/714,141

(22) Filed: Dec. 13, 2012

(51) Int. Cl. G01R 31/02

(52) U.S. Cl. CPC G01R 31/02
USPC 702/117

(57) ABSTRACT

In accordance with a preferred embodiment of the present invention, a method of testing a device includes a circuit includes a device-under-test and an emulated apparatus. The emulated apparatus includes digital circuitry that models a real device. The circuit is powered and a response of the circuit is calculated. The calculated response is determined at least based on the emulated apparatus. An analog response signal is generated based on the digitally calculated response. The analog response signal is applied to the device under test.

### TECHNICAL FIELD

The present invention relates generally to the field of testing and, in particular embodiments, to a method of testing a device using an emulated apparatus.

### BACKGROUND

Electronic devices are tested to obtain information about the operation of these devices. Certain industries, such as the automotive industry and the aerospace industry, require extensive testing before a product can enter the market to ensure safety. Automated testing is becoming more prevalent. The use of automated testing allows for testing a high volume of devices in a small amount of time with minimal human interaction. Using automated testing can be more efficient than other forms of testing by maximizing throughput and reducing human errors involved in testing. Test conditions, such as temperature, pressure, and time, can be automatically varied using automated testing. Both hardware and software are often utilized in automated testing, where the hardware interacts with the software. Software then controls the hardware, collects the data, analyzes the results, and prepares a report for an operator. An operator may be needed to connect the device under testing to the automated test setup, although this step may be automated.

Automated testing can involve the use of actual electronic devices that the device under testing will be connected to when the device is deployed in the real world. Using actual electronic devices allows for a realistic test environment. However, a single device may not display the range of acceptable electronic devices.

### SUMMARY OF THE INVENTION

An embodiment of the present invention provides a method of testing a device. A circuit includes a device-under-test and an emulated apparatus. The emulated apparatus includes digital circuitry that models a real device. The circuit is powered and a response of the circuit is calculated. The calculated response is determined at least based on the emulated apparatus. An analog response signal is generated based on the digitally calculated response. The analog response signal is applied to the device under test.

Another embodiment provides a method for emulating an apparatus. A circuit is caused to be closed so that a load unit is coupled is to a power source unit. The load unit or the power source unit comprises an emulation model. A response is digitally determined when the circuit is closed based on the emulation model. The digitally determined response includes an emulation delay relative to a response that would have occurred if neither the load nor the power source were an emulation model. The emulation model is updated based upon a time-shifted version of the response. The time-shifted version of the response is adjusted in time by an amount of delay less than the emulation delay. The circuit is then closed again so that the load unit is coupled is to the power source unit and a further response is digitally determined based on the updated emulation model when the circuit is closed again.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a system that includes components that can be tested using embodiments of the present invention;

FIG. 2 illustrates another system that includes components that can be tested using embodiments of the present invention;

FIG. 3 illustrates an embodiment system for testing a device;

FIG. 4 illustrates another embodiment system for testing a device;

FIGS. 5a-c illustrate current as a function of time graphs and sources of delay for embodiment systems for testing a device;

FIG. 6 illustrates an embodiment system for testing a device;

FIG. 7 illustrates an embodiment power amplifier;

FIGS. 8a-b illustrate current as a function of time graphs for an embodiment power amplifier;

FIG. 9 illustrates a table with performance parameters of an embodiment emulator;

FIG. 10 illustrates a diagram showing the development of an embodiment emulator;

FIGS. 11a-b illustrate LabVIEW block diagrams used in the development of embodiment load models;

FIG. 12 illustrates a table containing parameters that influence a lightbulb;

FIG. 13 illustrates an embodiment system for testing a device;

FIG. 14 illustrates another embodiment system for testing a device;

FIG. 15 illustrates the flowchart for an embodiment method for emulating an apparatus;

FIGS. 16a-b illustrate sequences of steps for an embodiment method for emulating an apparatus;

FIGS. 17a-f illustrate LabVIEW code for an implementation of an embodiment method for emulating an apparatus;

FIGS. 18a-b a digital trigger input voltage, load current, and error as a function of time graph for a method for emulating an apparatus; and

FIGS. 19a-e illustrate voltage as a function of time graphs, current as a function of time graphs, and a percent deviation as a function of time graph for an emulated lightbulb and a real lightbulb.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely the testing of a device using an emulated apparatus. The invention may also be applied, however, to other types of systems and methods.

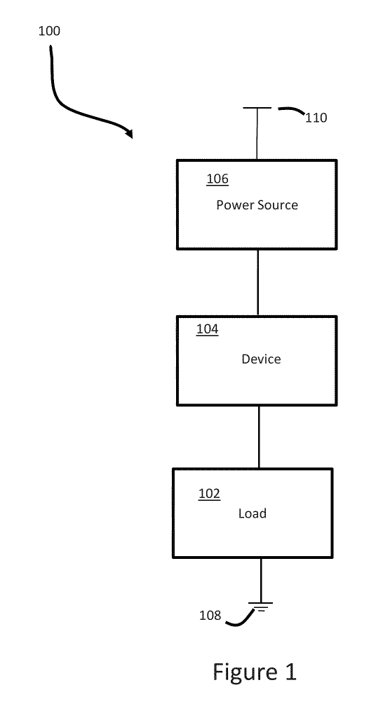

FIG. 1 illustrates a simplified embodiment of a system 100 that includes components that can be emulated. The general blocks of this system include a load 102 that is coupled to device 104, which is in turn coupled to power source 106. These blocks are illustrated as being coupled between a power source node 110 and a ground node 108. While just about any system can be emulated using concepts of the present invention, this simplified block diagram will be used to describe the basic concepts.

Load 102 provides a load to the system. For example, this element will produce a specific current when a given voltage is applied across it. Load 102 may exhibit a resistance, a capacitance, and/or an inductance. In one example, load 102 is an incandescent lightbulb. In other examples, load 102 may be a motor, such as a motor for windshield wipers, an LED, or another load, such as a microcontroller, a squib, or a xenon lighting module. In one aspect of the invention, the load 102 will be emulated in order to evaluate the device 104 or the power source 106.

Device 104 may be used to couple and/or uncouple load 102 to power source 106. In one example, device 104 is a switch, which closes to connect load 102 with power source 106 and opens to disconnect power source 106 from load 102. In one particular embodiment that will be described further below, device 104 may be a smart high side power switch, which may operate at a high current, such as 30 A, and may have protective features to shut down the switch if the current, voltage, or temperature exceeds a predetermined limit. In other examples, device under test 104 may be a complex battery management device which can handle several battery cells in parallel using complex active and passive balancing algorithms. Alternately, device 104 may be a linear voltage regulator or a DC/DC converter.

The element 106 is a power source. Power source 106 supplies power to load 102 when coupled to load 102 by device 104. In one example, power source 106 is a battery, for example, a lithium ion battery. In other examples, power source 106 could be a lead acid battery or an alternator. Power source 106 may be a real power source, or it may be an emulated power source. Power source 106 may be coupled to ground 108, as shown in FIG. 1.

If, for example, system 100 is used to test device 104, only one load 102, or a limited number of different loads, and only one power source 106, or a limited number of power sources, can be used in testing. However, in actual operation, there an acceptable range of parameters for load 102 and power source 106 that could be coupled to device 104. Load 102 or power source 106 can be simulated to test the reaction of device 104 to a range of parameters, but simulations might not be realistic.

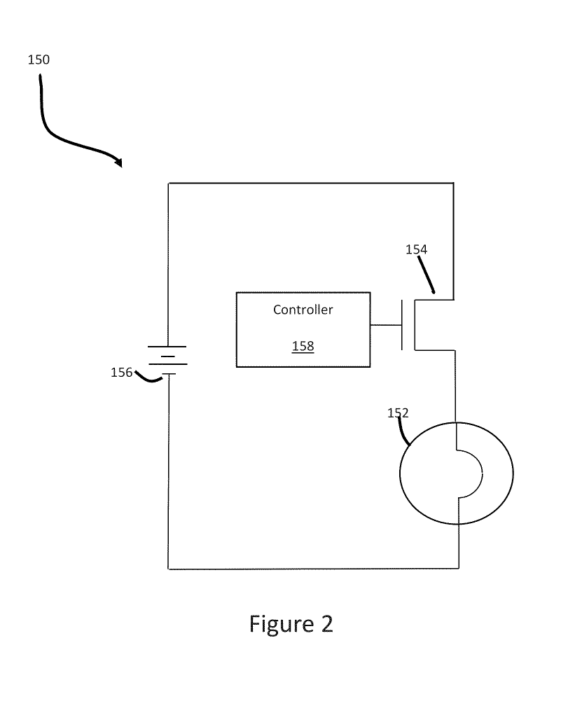

FIG. 2 illustrates system 150, one example of system 100. Load 102 of FIG. 1 is depicted by incandescent light bulb 152 in FIG. 2. Device 104 in FIG. 1 is depicted by power switch 154 in FIG. 2. Power switch 154 has a current path coupled between incandescent light bulb 152 and power source 156. Power source 156 (i.e. element 106 in FIG. 1) is depicted as a lithium ion battery in FIG. 2. System 150 may be deployed in an automobile, where, for example, incandescent light bulb 152 is a light bulb in a headlight and battery 156 is the car battery. Controller 158 controls the operation of power switch 154. For example, controller 158 might turn power switch 154 on to connect battery 156 to incandescent light bulb 152 to turn incandescent light bulb 152 on when a driver turns the headlights on.

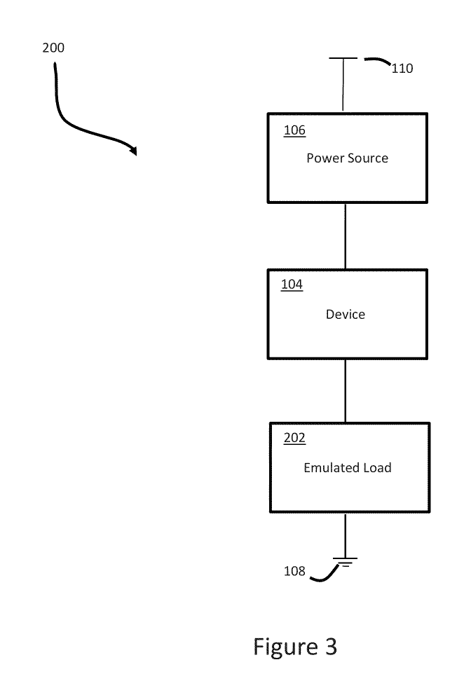

FIG. 3 illustrates embodiment system 200 for testing a device using an emulated load. The general blocks of this system include device 104, which is coupled to power source 106, which is coupled to ground 108. However, emulated load 202 replaces real load 102, which is in turn coupled to device under test 104. Emulated load 202 composes digital circuitry that models a real load. For example, a PID controller can be used to emulate a real load. In one example, such as the system of FIG. 2, emulated load 202 emulates an incandescent lightbulb. In other examples, emulated load 202 emulates a motor or an LED, a microcontroller, a squib or a xenon lighting module. Emulated load 202 may be configured to perform multiple iterations of calculations to emulate a real load. For example, emulated load 202 may digitally calculate a response based on a digital representation of the powering and a time-shifted version of a previous calculated response.

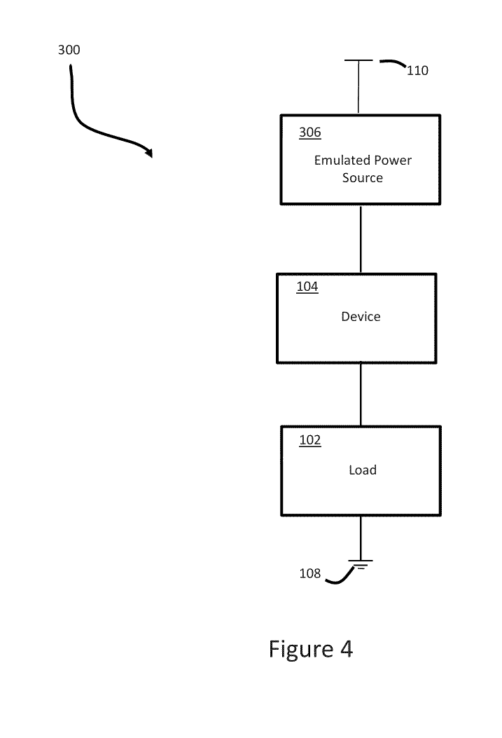

Another example is provided in FIG. 4, which shows embodiment test apparatus 300 for testing a device using an emulated power source. The general blocks of this system include a load 102, which is coupled to device 104. However, emulated power source 306 is coupled to device 104 instead of real power source 106. Emulated power source 306 contains digital circuitry that models a real power source. In one example, emulated load 202 emulates a battery, for example a lithium ion battery. In other examples, emulated power source 306 emulates a lead acid battery or an alternator. A similar method to that used by emulated load 202 in FIG. 3 to emulate a load may be used by emulated power source 306 to emulate a power source. Emulated power source 306 may be configured to perform multiple iterations of emulations. A response may be calculated based on a digital representation of a powering of the digital circuit and a time-shifted version of a previous calculated response.

It is understood that the embodiments of FIGS. 3 and 4 can be combined. For example, device 104 can be tested using an emulated load and an emulated power source.

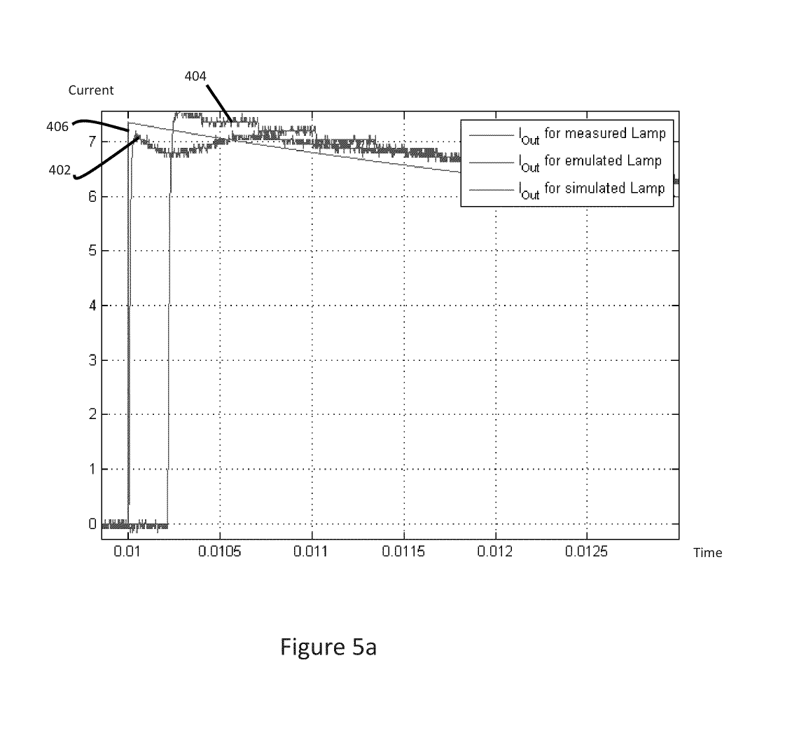

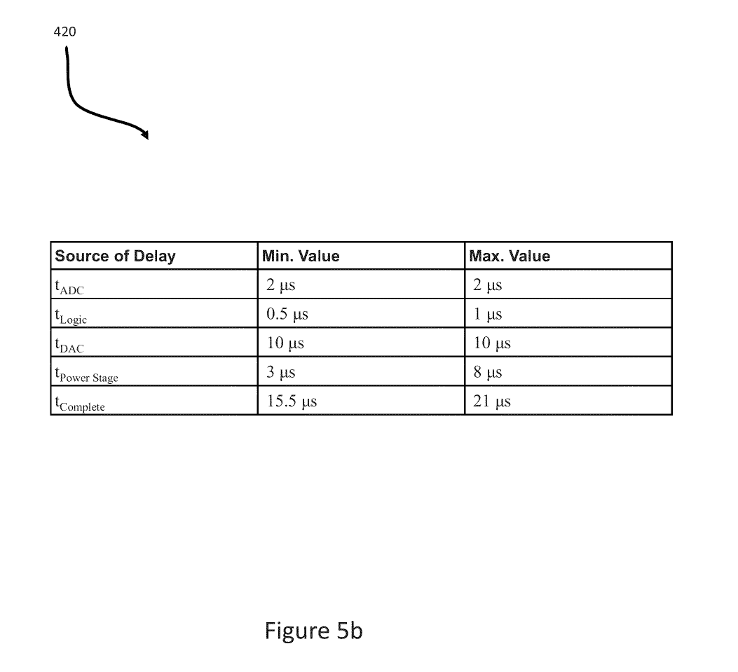

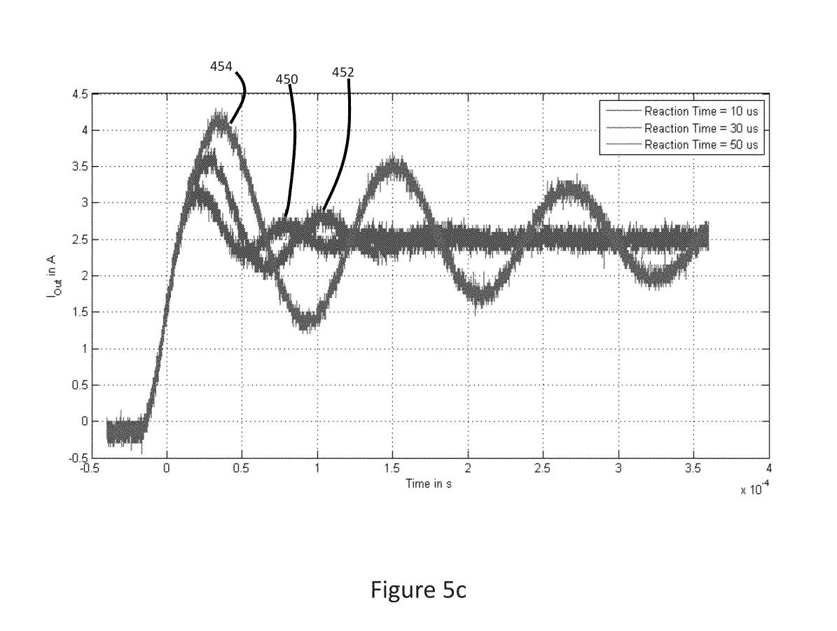

FIGS. 5a-c illustrate current as a function of time graphs and sources of delay for embodiment systems for testing a device. These figures compare responses of an emulated load, a real load, and a simulated load. When testing a device, such as device 104 in FIG. 1, the device may be coupled to real apparatus that the device would be coupled to in normal operation. For example, device 104 may be coupled to real load 102 and real power source 106, as illustrated in FIG. 1. More specifically, a smart power switch may be coupled to an actual incandescent lightbulb and am actual lithium ion battery.

Such a test provides a realistic snapshot of the interaction of smart power switch 154 with one particular incandescent lightbulb and one particular lithium ion battery. However, there is a range of acceptable parameters for incandescent lightbulbs and lithium ion batteries in the ordinary operation of the smart power switch that the switch should acceptably interact with.

One alternative to using a real apparatus is to use a simulated apparatus, which can simulate apparatus characteristics that span a range of acceptable values. However, a simulated apparatus might not provide a realistic view of behavior of real apparatus. An emulated apparatus can provide a realistic representation of the range of parameters a device under test would face in an actual environment.

FIG. 5a illustrates the current response, versus time, for a real incandescent lightbulb, a simulated incandescent lightbulb, and an emulated incandescent lightbulb. Response 402 shows the response of a real incandescent lightbulb, response 406 shows the response of a simulated incandescent lightbulb, and response 404 shows the response of an emulated incandescent lightbulb. As illustrated, response 406 of a simulated lightbulb is smoother than and not very similar to response 402 for a real incandescent lightbulb. However, while response 404 of an emulated lightbulb has a shape similar to that of response 402 for a real incandescent lightbulb, response 404 has an emulation time delay relative to response 402.

FIG. 5b illustrates some example sources of the emulation delay for an embodiment emulator in table 420. These times are merely provided as an example embodiment and it is understood that other systems could include other or different sources of delay. In an embodiment, an analog-to-digital converter has a known delay of 2 μs, and a digital-to-analog converter has a known delay of 10 μs. Additionally, logic has a minimum delay of 0.5 μs and a maximum delay of 1 μs, while a power stage has a minimum delay of 3 μs and a maximum delay of 8 μs. Thus, for this embodiment, the total minimum time delay is 15.5 μs while the total maximum time delay is 21 μs.

The emulation delay might cause oscillations in a PID controller in the emulator, as illustrated by FIG. 5c. Reaction 450 illustrates the reaction of a PID controller with a delay of 10 μs, reaction 452 illustrates the reaction of a PID controller with a delay of 30 μs, and reaction 454 illustrates the reaction of a PID controller with a delay of 50 μs. As the reaction time of the PID controller increases, oscillations in the response increase, leading to instability and inaccuracies in the emulation.

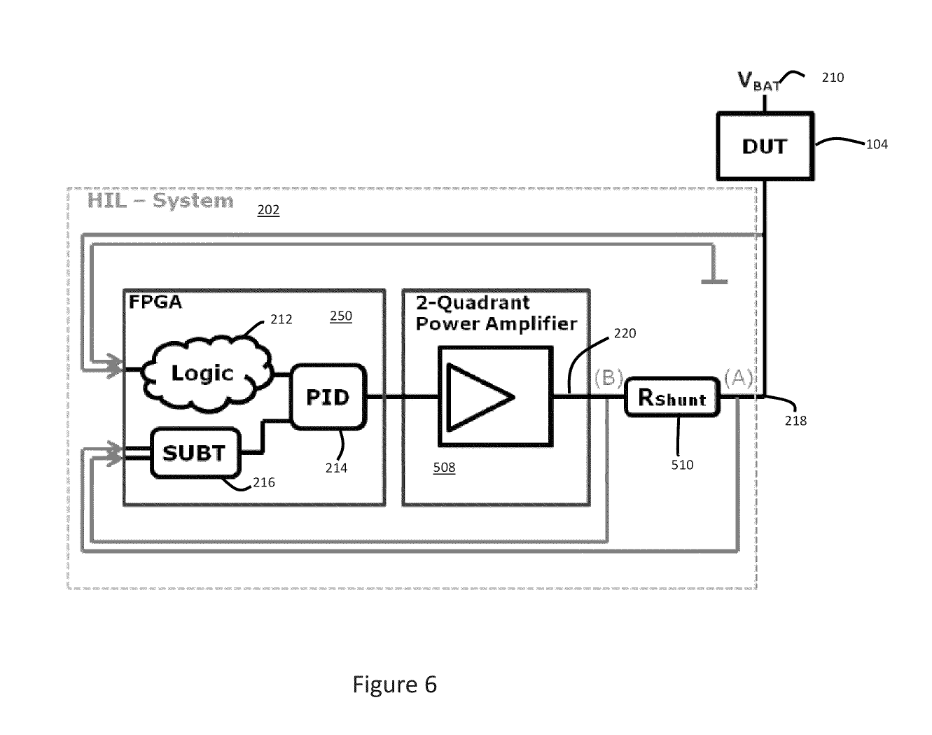

FIG. 6 illustrates emulated load 202 and device under test 104, an embodiment system that may be used to test device 104. Device 104, which may be a switch, is connected to V_{BAT} 210, the voltage from a power source, such as a battery. In an example, V_{BAT} 210 may range from about 0 V to about 24 V. Additionally, device 104 is coupled to emulated load 202, which may emulate an incandescent lightbulb. In some embodiments, emulated load 202 may operate at a high power, for example with current levels of 90 A. Emulated load 202 may be configurable to emulate multiple apparatus. For example, emulated load 202 may be capable of being configured to emulate an incandescent lightbulb, a motor for windshield wipers, and a lithium ion battery. Further, emulated load 202 may be a closed loop system with real time emulation capability.

In an example, emulated load 202 has a signal processing unit and a current source. For example, a signal processing unit 250 may be on an FPGA, a digital signal processor (DSP), or a microprocessor target. The signal processing unit 250 contains logic 212, which contains a load model and calculates the current value for device under test 104 when a voltage is applied. Additionally, the signal processing unit 250 may contain subtractor unit 216, which calculates the voltage difference across shunt resistor 510, voltage 220 minus voltage 218. Also, the signal processing unit may contain PID controller 214, which, together with power amplifier 508, is the current source. Power amplifier 508 may be a two quadrant power amplifier. In an example, power amplifier 508 may be capable of sinking current for ohmic loads such as incandescent lightbulbs and inductive and/or capacitive loads such as motors or batteries. In an embodiment, device 104 is connected to a PXIe System, and automation is controlled using GPIB and PXI busses.

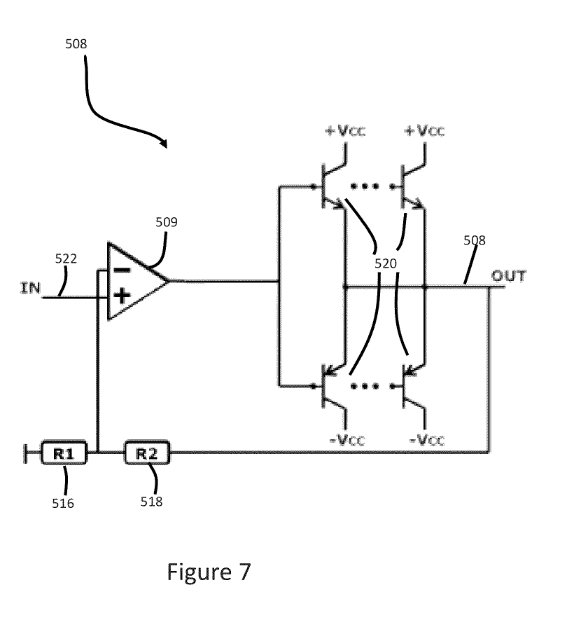

FIG. 7 illustrates an example of a power amplifier 508, which may be used in an embodiment emulator. Power amplifier 508 contains parallel driven complementary power transistors with high collector current 520. The output of op amp 509 is connected to parallel driven complimentary power transistors with high collector current 520, which produce power amplifier output 508. Also, power amplifier input 522 is connected to the positive input terminal of op amp 509. The negative terminal of op amp 509 is between resistor 516 and resistor 518, which is also coupled to power amplifier output 508.

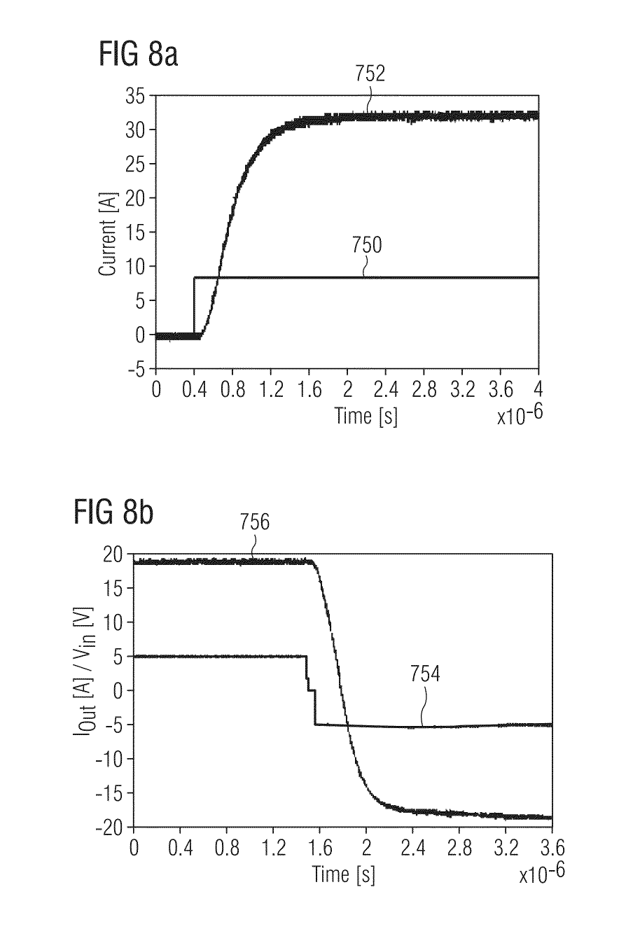

FIGS. 8a-b illustrate graphs demonstrating the current response versus time of power amplifier 508. FIG. 8a illustrates current response 752 of power amplifier 508 to step input 750. A step from 0 A to 32 A of the input of power amplifier 508 has a settling time of 8 μs. Similarly, FIG. 8b illustrates the transition between two quadrants of the power amplifier 756 to step input 754 for power amplifier 508, which also has a reaction time of 8 μs.

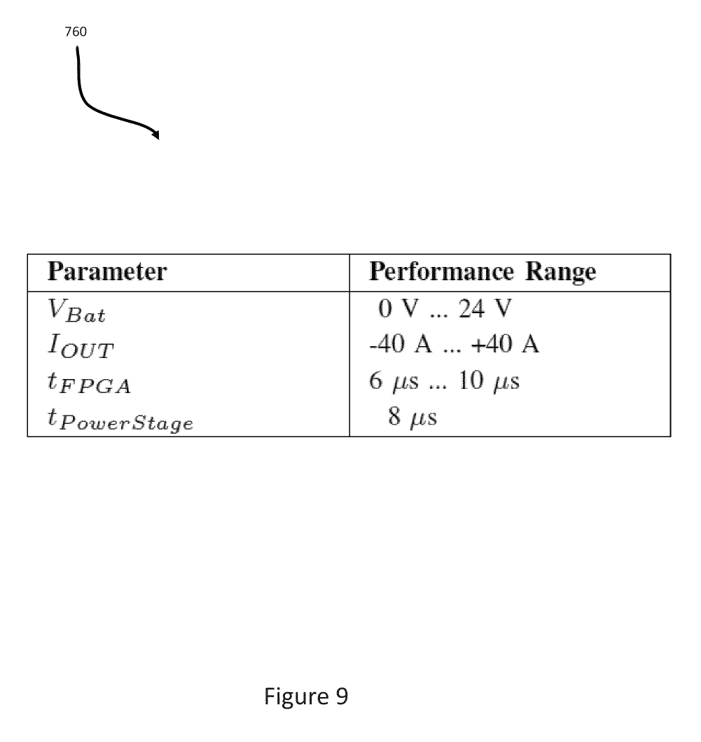

FIG. 9, which contains table 760, illustrates parameters for an embodiment emulator. In an embodiment, the digital-to-analog conversion has a sampling period from about 6 μs to about 10 μs, while the input voltage ranges from about 0 V to about 24 V. Also, output current ranges from about −40 A to about 40 A, while the time delay in the power stage is about 8 μs. Alternately, the sampling period, input voltage, output current and time delay may have other values.

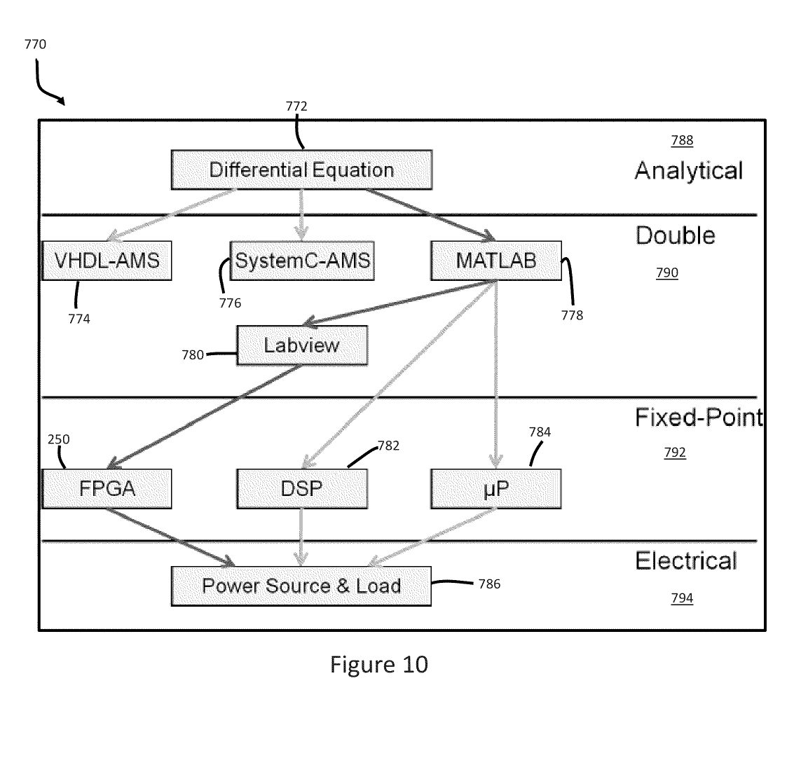

FIG. 10 illustrates a hierarchy for load emulation model development 770, which may be used to develop an embodiment emulator. These parameters are merely provided as an example embodiment and it is understood that other emulators could include other or different parameters. Hierarchy for load emulation model development 770 contains analytical layer 788, double layer 790, fixed-point layer 792, and electrical layer 794. Analytical layer 788 involves differential equations 772 which model the behavior of the emulated apparatus, which may be a load, a power source, or another apparatus. Also, double layer 790 contains load models in languages such as VHDL_AMS 774, SystemC-AMS 776, and MATLAB/Simulink 778. Additionally, fixed-point layer 792 may be implemented by FPGA 250, DSP 782, or a μP target 784. In embodiments involving DSP 782 or μP target 784, MATLAB load model 778 may be coded in an automated way. In an embodiment using FPGA 250, LabVIEW code 780 is translated from MATLAB load model 778 to get from differential equations 772 to an executable digital load model that can be implemented on an FPGA without the need of any implicit solver algorithm in a semi-automated way. Fixed point level 792 interacts with electrical level 794, which contains power source and load 786.

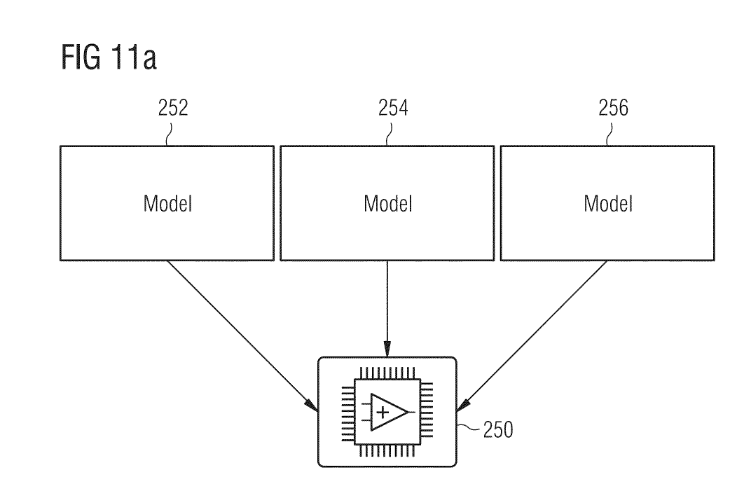

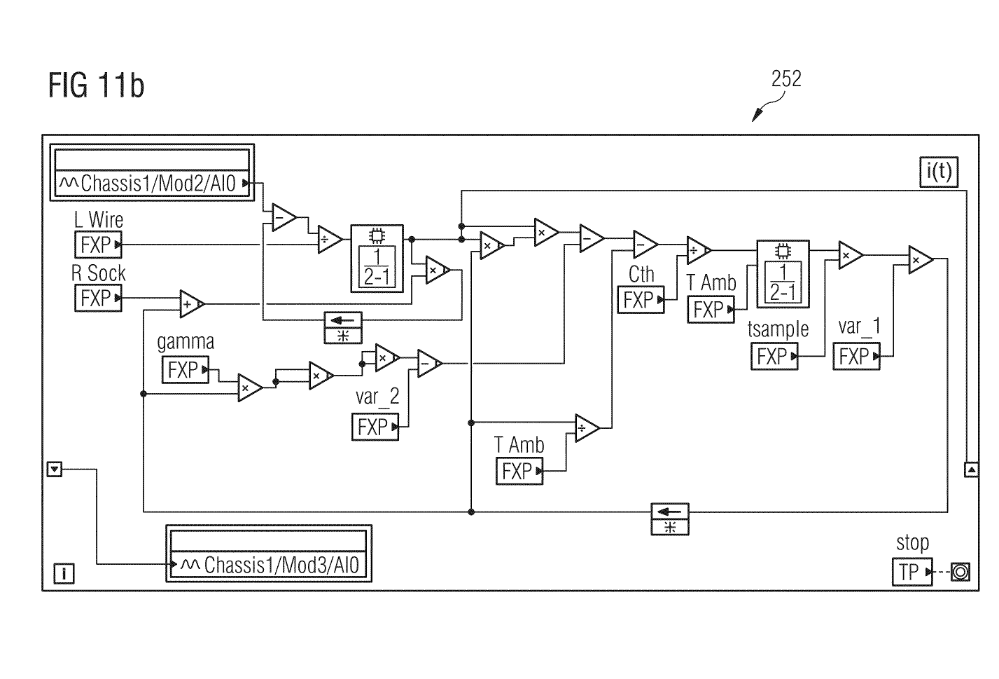

FIGS. 11a-b illustrate a procedure for developing a load model for real-time load emulation in for FPGA 250 using LabVIEW. FIG. 11a illustrates the design of various embodiment emulation models for use on FPGA 250. LabVIEW code includes a block diagram which graphically illustrates the dataflow, a front panel, and a connector panel. The front panel may be used independently as a graphical user interface or it may depict inputs and outputs through the connector panel if used as a subroutine. Model 252 illustrates a LabVIEW block diagram for a load model of an incandescent lightbulb, model 254 illustrates a LabVIEW block diagram for a load model of a motor, and model 256 illustrates a LabVIEW block diagram for a load model of a microcontroller. The LabVIEW code may be downloaded to run on an FPGA.

FIG. 11b illustrates LabVIEW code for an emulation model for an incandescent lightbulb. Starting with the physical equations, Kirchoff's law for electrical meshes, which considers the influence of wire resistance, wire inductance, and the thermo-electrical model of the lightbulb on the load current, is given by:

$${μ}_{HS} ( t ) = {R}_{Wire} \cdot i ( t ) + {L}_{Wire} \cdot \frac{d i}{d t} + R ( T ) \cdot i ( t ) .$$

In this equation, μ_{HS} is the time-variant output voltage of the high-side switch, R_{wire} and L_{wire} are the resistance and inductance of the wire, i(t) is the load current as a function of time, and R(T) is the thermal-dependent resistance of the filament. Additionally, a load-specific equation, depending on electro-thermal or electro-mechanic loads is used. The load specific equation may be thermal heating when modeling incandescent lightbulbs or back electro-motive force when modeling motors.

In a load model of an incandescent lightbulb, energy conservation is illustrated by:

Pₑₗ=P_{rad}+P_{cond}+C_{th,fil}·\dot{T}_{Fil},

where Pₑₗ is the total electrical power, P_{rad} is the radiated power, P_{cond} is the conductive power, and Cₜₕ·\dot{T}_{Fil} is thermal heating power. \dot{T}_{Fil} is found in:

$${\dot{T}}_{Fil} = \frac{1}{{c}_{th} , fil} ( R ( T ) \cdot {i}^{2} ( t ) - {γ ( {T}_{Fil} - {T}_{Amb} )}^{4} - \frac{{T}_{Fil}}{{R}_{th , Fil}} ) ,$$

where C_{th,fil} is the heat capacity of the filament, R_{th,Fil} is the thermal resistance of the filament, T_{Fil} is the filament temperature, and T_{Amb} is the ambient temperature. The thermal-variant resistance is given by:

$$R ( T ) = {{R}_{Fil , nom} ( \frac{{T}_{Fil}}{{T}_{Fil , nom}} )}^{ρ} ,$$

where T_{Fil,nom} is the filament temperature at nominal power and R_{Fil,nom} is the resistance at nominal power.

To implement these equations in an FPGA, the equations may be transformed from differential equations to a set of first order difference equations. The sampling time is equal to the processing time of one loop cycle, which may be about 7 μs. Time invariant factors may be calculated in a pre-processing step to optimize the digital design. A similar procedure may be used to determine an emulation model for other apparatus, such as motors and batteries, or even full applications like motor and throttle.

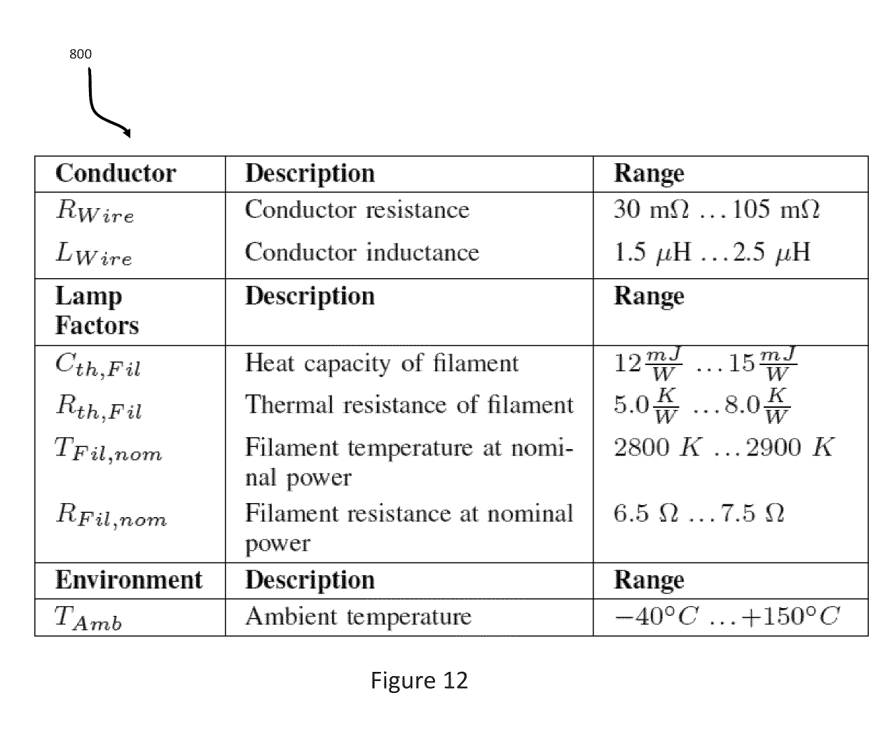

FIG. 12 illustrates table 800, which includes parameters of an incandescent lightbulb model for a 21 watt incandescent lightbulb. These parameters are merely provided as an example embodiment and it is understood that other models could include other or different parameters. Conductor resistance varies from about 30 mΩ to about 105 mΩ, while conductor inductance varies from about 1.5 μH to about 2.5 μH. Also, the heat capacity of the filament ranges from about 12 mJ/W to about 15 mJ/W, while the thermal resistance of the filament ranges from 5 K/W to about 8 K/W. Additionally, the filament temperature at nominal power may range from about 2800 K to about 2900 K, while the filament resistance at nominal power may vary from about 6.5Ω to about 7.5Ω. Finally, the ambient temperature may range from about −40 degrees Celsius to about 150 degrees Celsius. It is understood that these values are merely an example. Alternately, incandescent lightbulb of a different wattage is used. The values for the conductor resistance, conductor inductance, heat capacity of the filament, the filament temperature at nominal power range, resistance at nominal power, and ambient temperature range may be other values.

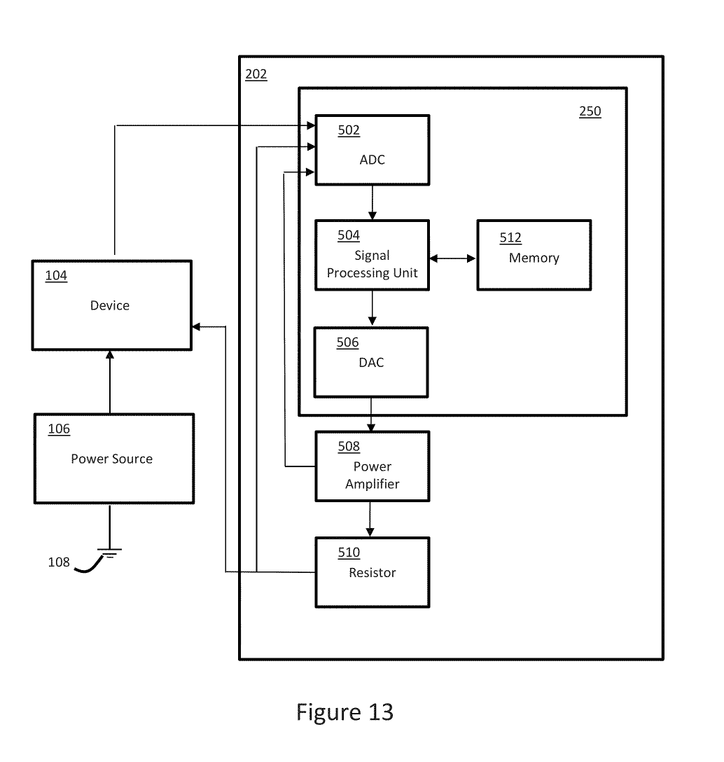

FIG. 13 illustrates an embodiment system for testing a device using an emulator to emulate a load. Initially, emulated load 202 is powered, for example by applying a voltage or a current to emulated load 202 by connecting power source 106 to emulated load 202 by closing a switch in device under test 104. After that, analog-to-digital converter 502, which may be on the same chip as FPGA 250, converts the electric power to a digital representation. Next, signal processing unit 504, which may also be part of FPGA 250, digitally calculates a response based on an emulation model and the digital representation of the electric power. Alternately, signal processing unit 504 may be a DSP or a μP target. The emulation model may be updated for each iteration based on a time-shifted version of the digitally calculated response of a previous iteration. After calculating the response, a version of the calculated response is saved in memory 512. In an example, memory 512 may FPGA RAM.

Next, digital-to-analog converter 506, which may be on FPGA 250, converts the digital calculated response to an analog response and power amplifier 508 amplifies the analog response. In an example, power amplifier 508 is a class AB power amplifier, which may be capable of operating at a current level of 90 A. The output of power amplifier 508 is fed back to analog-to-digital converter 502. Next, the analog response passes through resistor 510, the output of which is also fed back to analog-to-digital converter 502. The analog response is also applied to device 104, which reacts to the analog response.

Finally, signal processing unit 504 determines if another of a plurality of iterations of will be performed. For example, signal processing unit 504 may determine that another iteration will be performed if the new error is less than the old error. If signal processing unit 504 determines that another iteration will be performed, emulated load 202 is powered, followed by analog-to-digital converter 502 converting the electric power to a digital representation. Next, signal processing unit 504 calculates a digital response based on the digital representation of the electric power and on a time-shifted version of the previous reaction, where the time shift is Δt. Then, the digital response is converted to an analog response by digital-to-analog converter 506. The analog response passes through power amplifier 508 and resistor 510, and is applied to device under test 104. These steps repeat for a plurality of n iterations until the total time shift ΔT is approximately equal to the emulation delay.

The emulation delay may be determined based on known sources of delay, such as analog-to-digital converter 502, signal processing unit 504, digital-to-analog converter 506, and power amplifier 508. The emulation delays in analog-to-digital converter 502 and digital-to-analog converter 506 are constant time delays for a given device. On the other hand, the emulation delay for calculations in signal processing unit 504 is a variable delay that depends on the logic implemented, which can be extracted from the logic design, and is constant for a particular implementation. Also, the delay of power amplifier 508 is a variable delay. In an example, the total time shift ΔT may be equal to the approximate emulation delay, which may be from about 15 μs to about 21 μs.

In an example, time shift Δt may be a function of ΔT, (the emulation delay,) n, (the total number of iterations,) and i, (the iteration number,) where Δt(0)=0. In an example, the time shift is less than the emulation delay. The time shift for each iteration may be the same each time the time shift is performed, such that Δt(i)=Δt(i−1)+ΔT/n. However, the incremental time shift may vary, for example the time shift may gradually approaches ΔT. For example, Δt(i)=Δt(i−1)+ΔT/2ⁱ. Alternately, Δt(i) may be a logarithmic function of i.

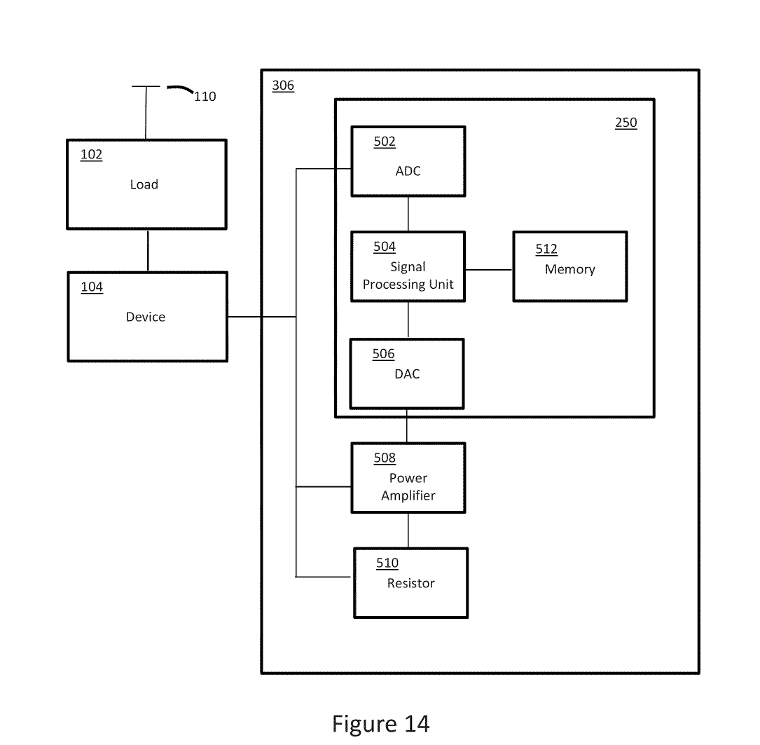

FIG. 14 illustrates an embodiment system to test a device using emulated power source 306 to emulate a power source. In an example, emulated power source 306 operates in a manner similar to emulated load 202. However, emulated power source 306 differs in that no PID controller and no external resistor is required.

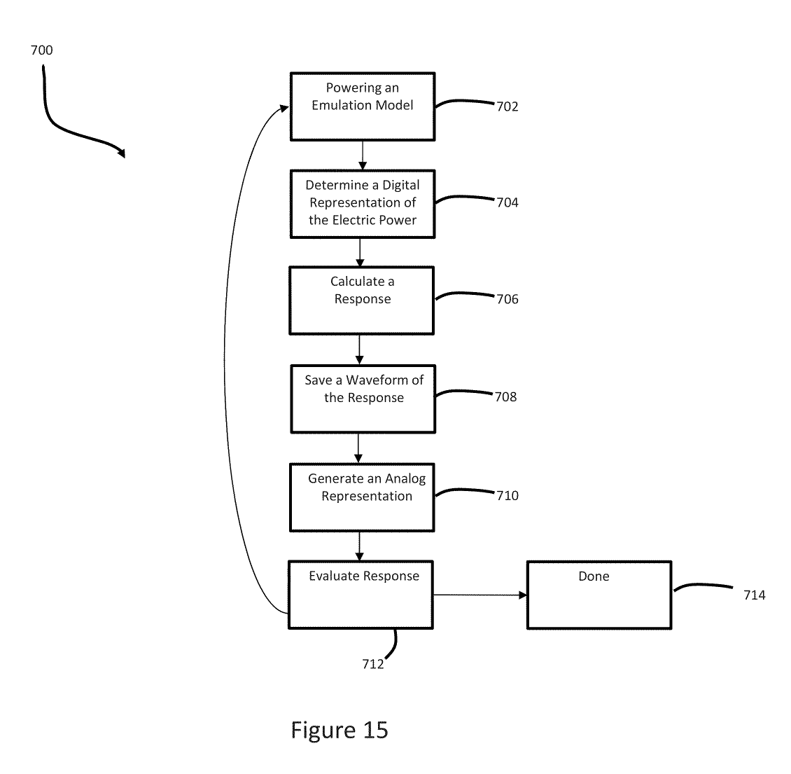

FIG. 15 illustrates a flowchart of method 700 for an embodiment system of testing using an emulated apparatus. The emulated apparatus may be an emulated load and/or an emulated power source, and/or another apparatus, in particular an apparatus operating at a high current. First, method 700 powers a digital circuit containing an emulation model in step 702, which may be performed my connecting an emulation circuit of a load to a real power source by closing a switch. More specifically, an emulator of an incandescent lightbulb may be connected to a real lithium ion battery by closing a real smart power switch. Alternately, an emulator of a power source may be connected to a real load by closing a switch. In particular, an emulator of a lithium ion battery may be connected to a real incandescent lightbulb by closing a real smart power switch. Alternately, an emulator of a load may be connected to an emulator of a power source by closing a real switch. Another method of connecting an emulator to an apparatus may be used, such as a linear voltage regulator and emulate microcontroller load steps, a squib driver and emulate squib.

Next, step 704 involves determining a digital representation of the applied electric power, which may be performed by using a digital-to-analog converter, which may be on an FPGA. Alternately, step 704 may be performed on a DSP or a microprocessor target. Then, in step 706, a response is calculated using an emulation model, which may be performed, for example, on an FPGA. Alternately, step 706 may be performed on a DSP or a microprocessor target. The emulation model may be based on the digital representation of the applied electric power and/or from a time-shifted version of the digitally calculated response of a previous iteration. Step 708 saves a waveform of the calculated response. In an example, the waveform may be saved in RAM, which may be FPGA RAM. Alternately, the waveform may be saved in an external memory.

After step 708, in step 710, an analog response is generated from the digitally calculated response. Step 710 may be performed by an analog-to-digital converter, which may be on an FPGA. Alternately, step 710 may be performed on a DSP or a μP target. The analog response is amplified by a power amplifier, which may be a class AB power amplifier. Next, the analog response pass through a resistor and it is applied to the device under test. A voltage drop may be measured across the resistor. In an example, the device under test may be a smart power switch, or it may be a linear voltage regulator, a DC/DC converter or a squib driver. The device responds to the applied analog response. Finally, step 712 evaluates the response. If the emulation is complete, for example if the new error is greater than the old error, the emulation goes to step 714 and the emulation stops.

If the emulation is not complete, the emulator performs another iteration of emulation, beginning with powering the emulation model in step 702. Following that, a digital representation of the electrical power is determined in step 704, and a response is calculated based on the digital representation of the electrical power and based on a time shifted version of a previous response. The saved waveform may be shifted by an incremental time shift, which may be uniform for each of a plurality of iterations, or may gradually approach the total time shift. Then, a waveform of the digital response is saved to be used by a subsequent iteration. After that, an analog representation of the digital response is produced in step 710, and it is applied to the device under test. Finally, the response is evaluated in step 712. If the emulation is complete, the emulation proceeds to step 714, and the emulation finishing. In an example, the emulation model used is the emulation model of the previous step. If the emulation is not complete, the emulator repeats steps 702, 704, 706, 708, 710, and 712 until the emulation is complete, for example until the new error is greater than the old error.

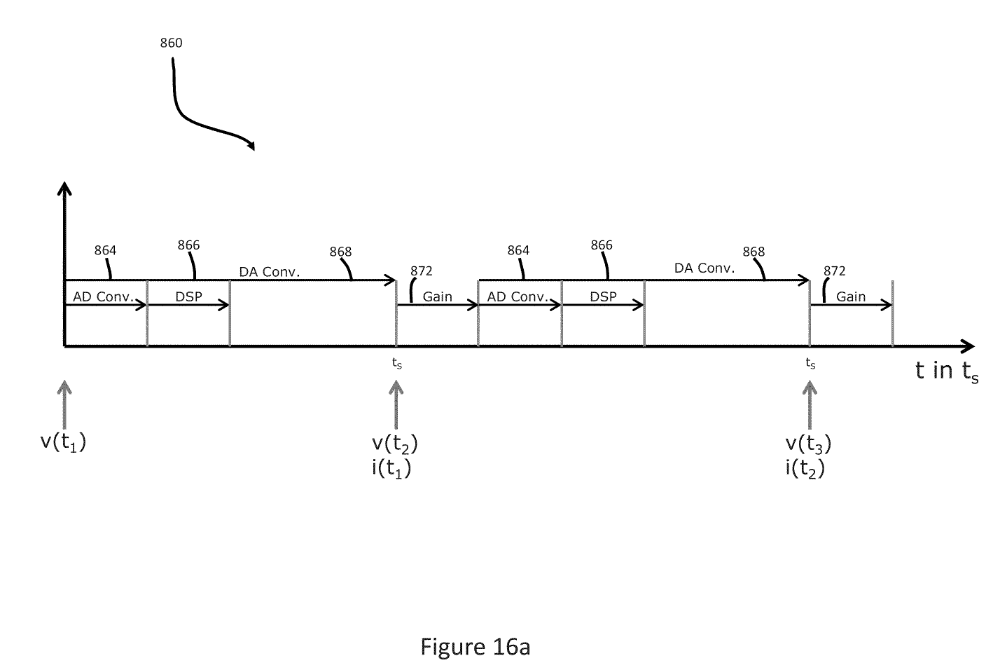

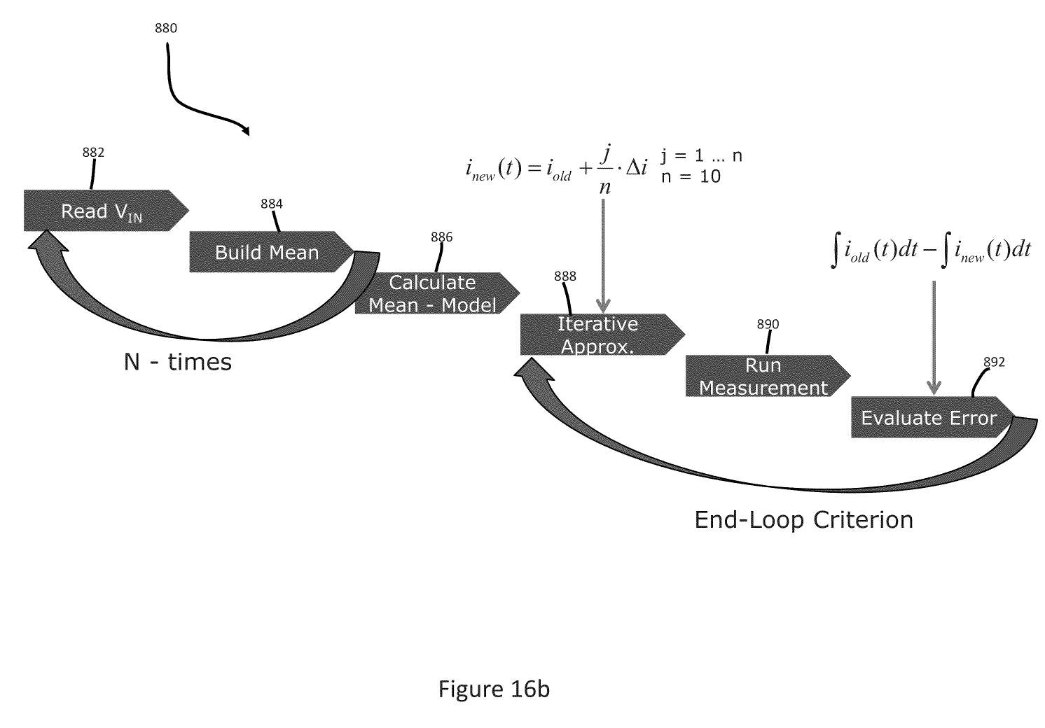

FIGS. 16a-b illustrate steps for an embodiment method of emulating an apparatus. FIG. 16a illustrates a sequence of steps for of emulation as a function of time. Initially, at time t1, an input voltage is applied. Next, analog to digital conversion 864 is performed on the input voltage and a DSP performs calculations 866 on the digital signal. After that, digital to analog conversion is performed 868 on the calculated digital value thereby generating a load current i(t1). As discussed above, the load current will not be a true replica of the ideal load current because of delays introduced by the conversion and calculation steps 864-868.

Following that, a voltage is applied at time t2 with the current from time t1. In this case, a gain 872 is applied. Steps 864, 866, and 868 are repeated after the gain is applied. From these calculations, a new load current and voltage can be derived. These steps may be repeated until the desired result is obtained.

FIG. 16b illustrates method 880 for emulating an apparatus. Initially, in step 882, the input voltage is read in. In step 884, a mean value of the input voltage is built. Step 882 and step 884 are repeated N times, where N is an integer corresponding to the number of times the mean value will be calculated. Next, in step 886, a load current is calculated from the mean voltage.

Then, an iterative approximation is performed in step 888. The new current is calculated to be:

$${i}_{new} ( t ) = {i}_{old} + \frac{j}{n} \cdot Δ i ,$$

where i_{new}(t) is the new current value, i_{old} is the previous current value, n is the maximum number of time steps, j is an integer between 1 and n that indicates the iteration number, and Δi is the change in current. In an example, n is 10, although n may be another integer. Then, in step 890, a measurement is performed.

Finally, in step 892, the error is evaluated. The error is:

∫i_{old}(t)dt−∫i_{new}(t)dt

If the new error is less than the old error, another iteration is performed by repeating step 888, step 890, and step 892. If the new error is greater than the old error, the iteration is complete, and the current used is the current from the previous iteration with the smallest error.

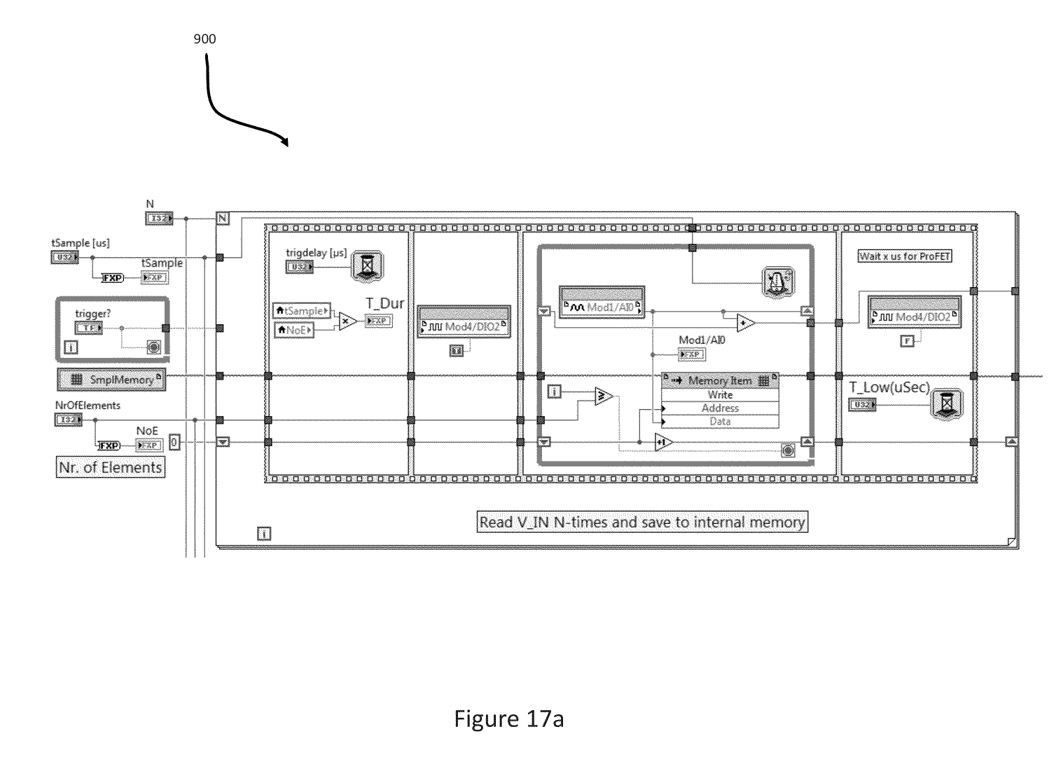

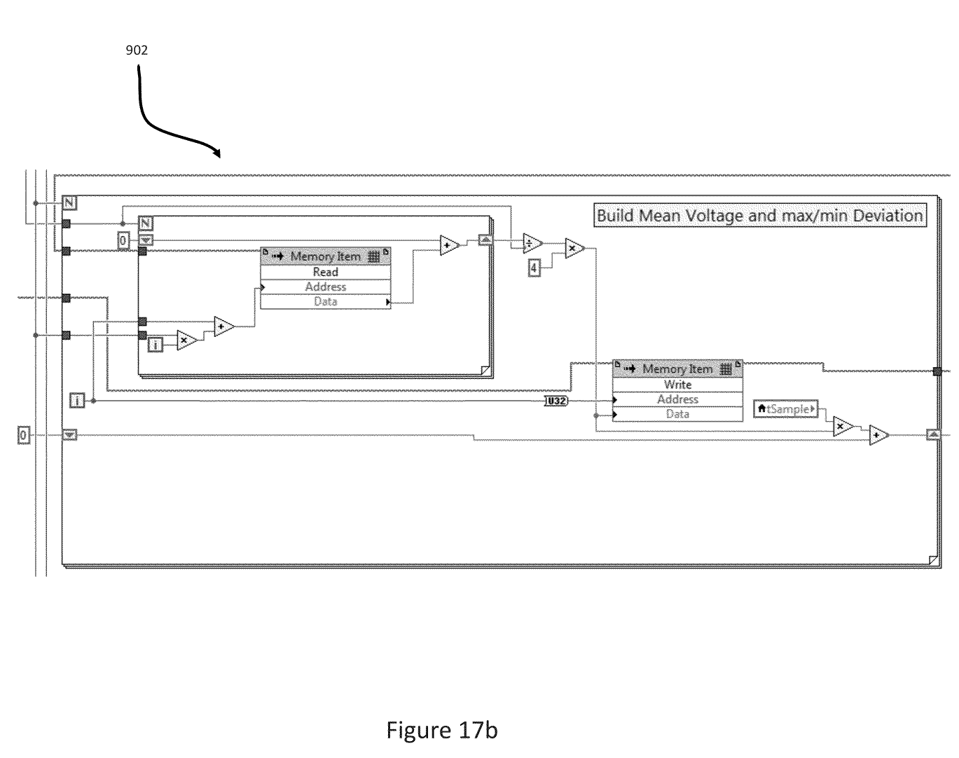

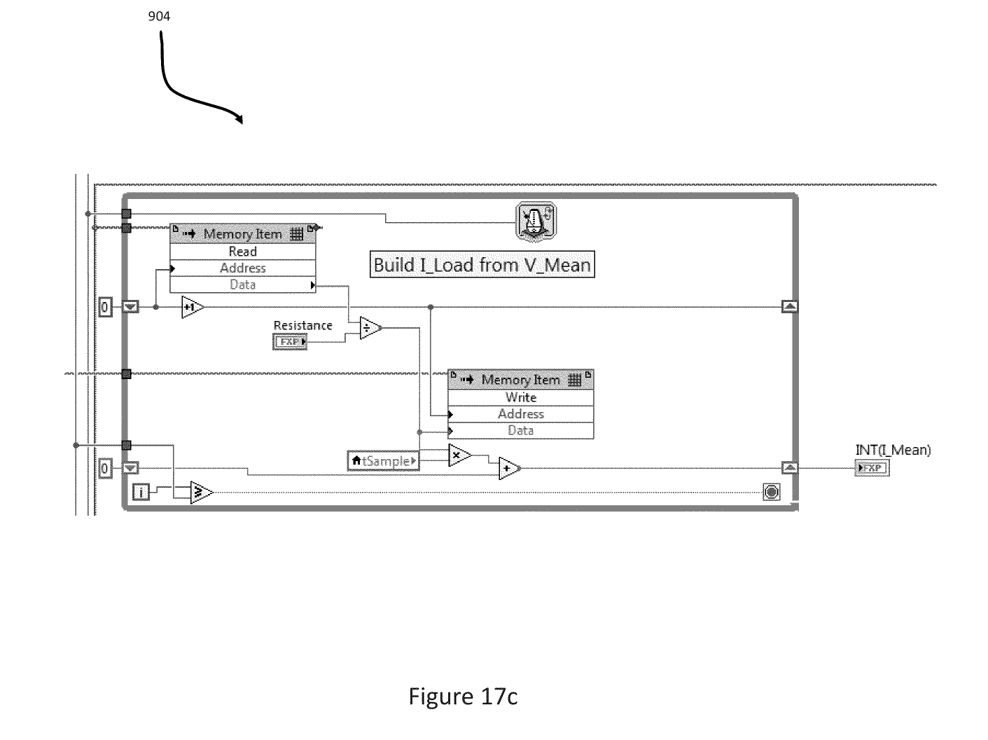

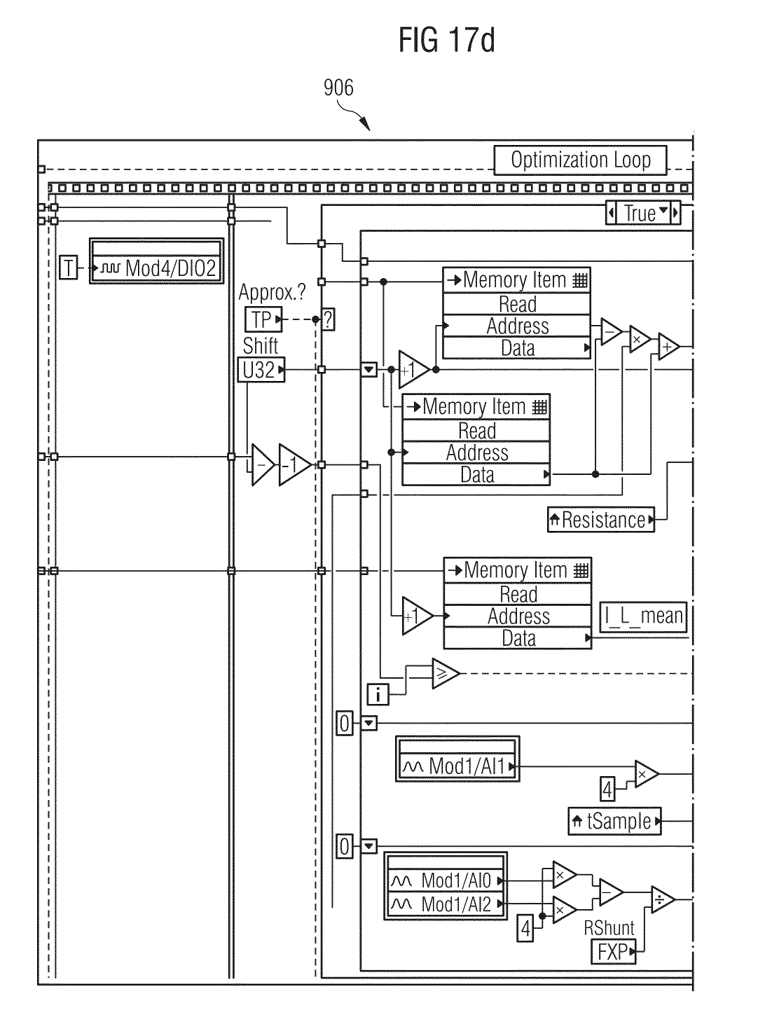

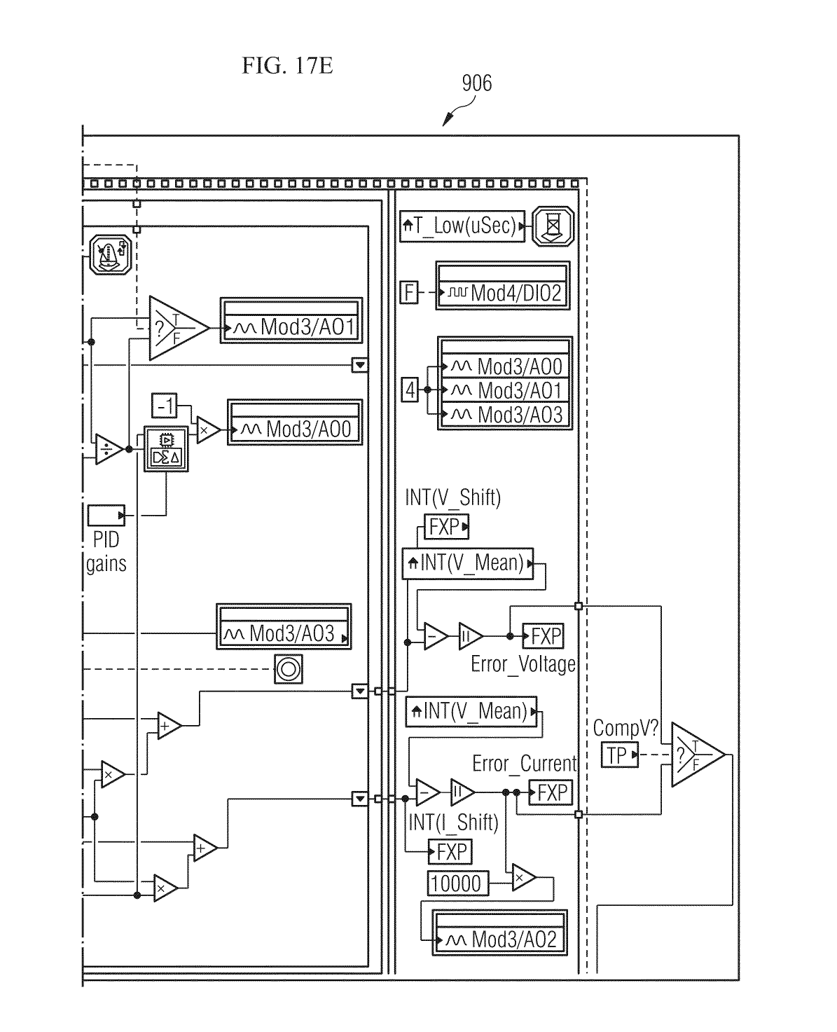

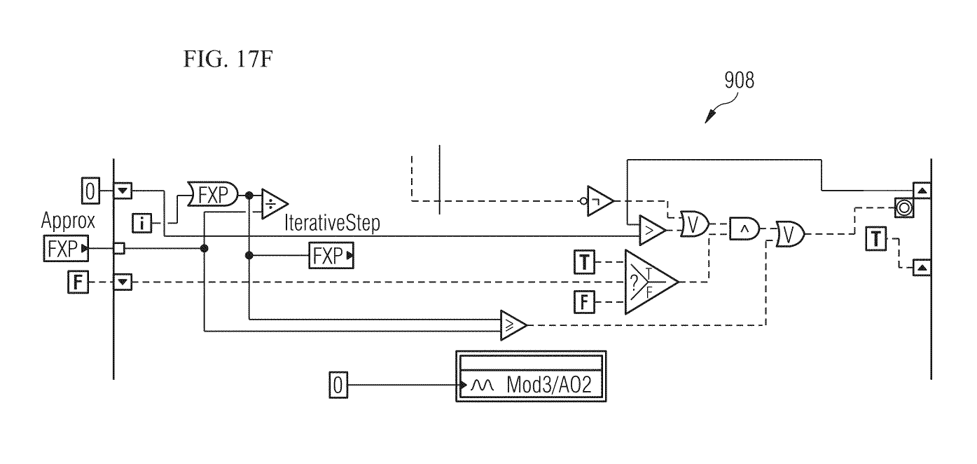

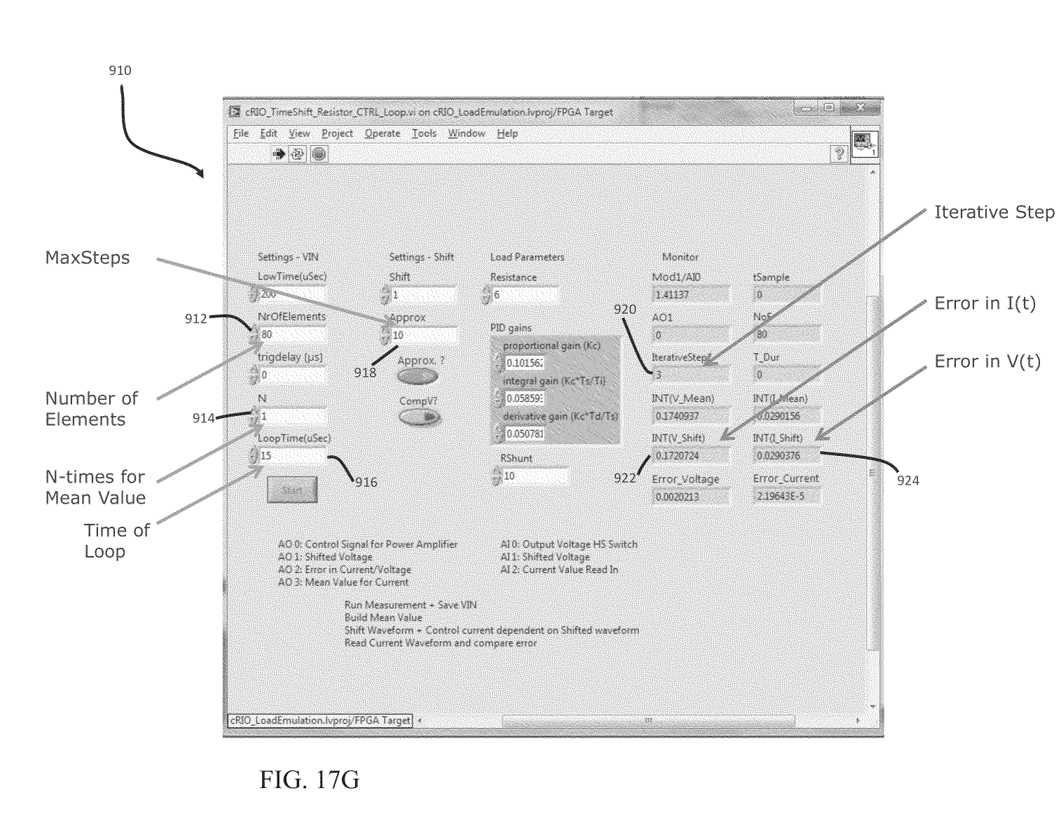

FIGS. 17a-f illustrate LabVIEW code that may be utilized in an embodiment system for testing a device. This code is merely provided as an example and it is understood that different code may be used in other situations. The LabVIEW code may be run on an FPGA.

FIG. 17a illustrates LabVIEW block diagram 900 for implementing step 882 for reading in an input voltage, while FIG. 17b illustrates LabVIEW block diagram 902 for implementing step 884 for building a mean value of the input voltage. Also, FIG. 17c illustrates LabVIEW block diagram 904, which implements step 886 by calculating a load current from the mean voltage. FIG. 17d illustrates LabVIEW block diagram 906, which implements step 888 calculating a new current, step 890 performing a measurement, and step 892 calculating the error. Additionally, FIG. 17e illustrates LabVIEW block diagram that ends the emulation if the new error is greater than the old error. FIG. 17f illustrates LabVIEW front panel 910 corresponding to the block diagrams in FIGS. 17a-17e. The inputs of front panel 910 include the number of elements 912, the number of times to calculated mean value 914, the time for a loop 916, and the maximum number of steps 918, while the outputs include the iterative step 920, the error for the current 922, and the error for the voltages 924.

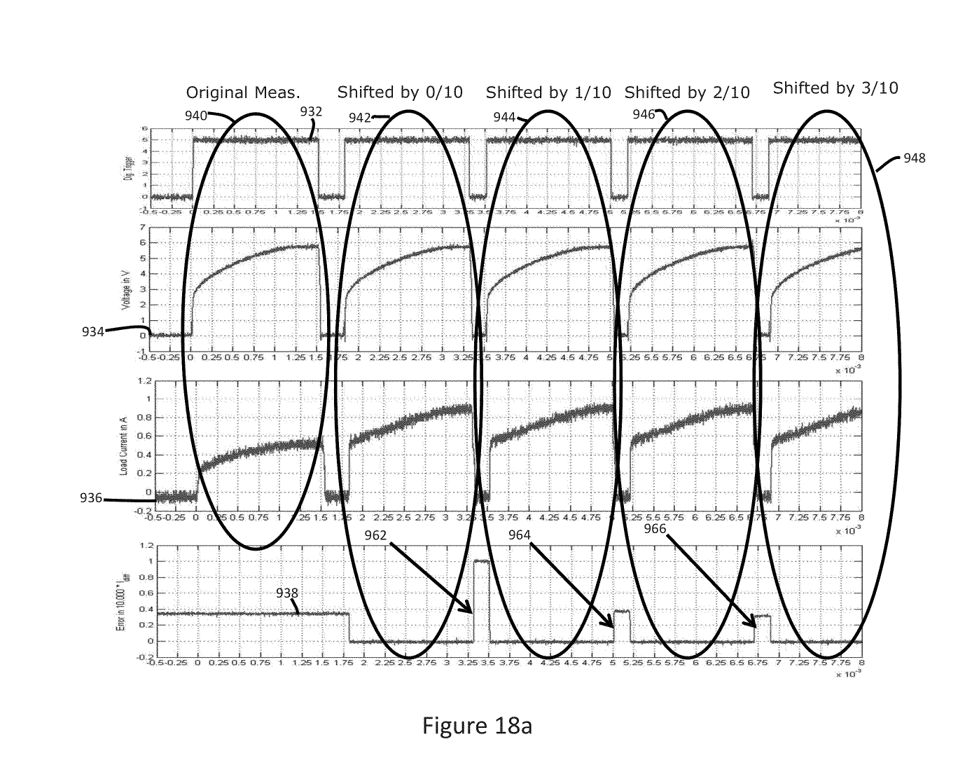

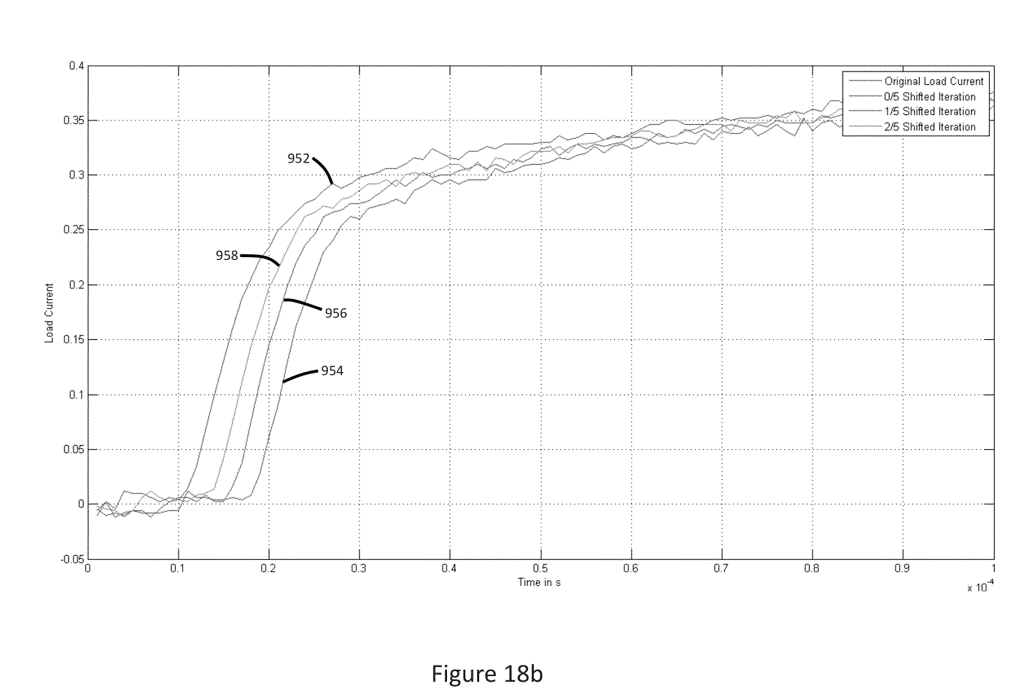

FIGS. 18a-b illustrate results of an embodiment system for emulating a device. FIG. 18a illustrates digital trigger signal 932, input voltage 934, load current 936, and error 938 for an original measurement 940 and several shifted measurements 942-946. Upon a rising edge of the digital trigger signal 932, an input voltage 934 is applied to the circuit, which in turn causes a load current 936 to be generated within the circuit. In this manner a baseline measurement can be obtained by the original measurement 940.

In the embodiment being discussed now, a number of iterations of measurements will be performed. In the first iteration 942 (labeled as 0/10, since up to ten iterations will be performed in this embodiment), an input voltage and consequent load current are determined upon a rising edge of the trigger signal 932. Based on comparison with the original measurement 940, an error pulse 962 is generated within error signal 938.

A second iteration 944 (labeled 1/10) is then performed to generate a second error pulse 964. Since the magnitude of the second error pulse 964 was less than the magnitude of the first error pulse 962, another iteration 946 is performed. Based on this next iteration (labeled 2/10), a third error pulse 966 is generated. Once again, this error pulse 966 is compared with the previous error pulse 964 and, since it has once again become smaller, another iteration 948 is performed.

In the illustrated example, the iteration 948 is the last iteration because the fourth error pulse (which has been cut off from this view) was greater than the third error pulse 966. Because the error went up, it can be assumed that the iteration 946 utilized the optimal delay and, therefore, this emulation is utilized. If the error had once again gone down, the iterations would continue either until the error goes up or the maximum number of iterations (ten in this example) is reached. The maximum number is set to cap the time that can be spent performing the emulation.

FIG. 18b illustrates the load current versus time for an original measurement, for no shift, a shift of one, a shift of two, and a shift of three. The current versus time curve for a no shift 954 is to the right of original measurement curve 952, while the current versus time curve for a shift of one 956 is closer to original measurement 952. Similarly, current versus time curve for a shift of two 958 is closer to original measurement 952 than curve for a shift of one 956. However, current versus time curve for a shift of three (once again not pictured) is to the left of original measurement curve 952, indicating an inaccurate emulation, where the emulated model responds before the voltage is applied.

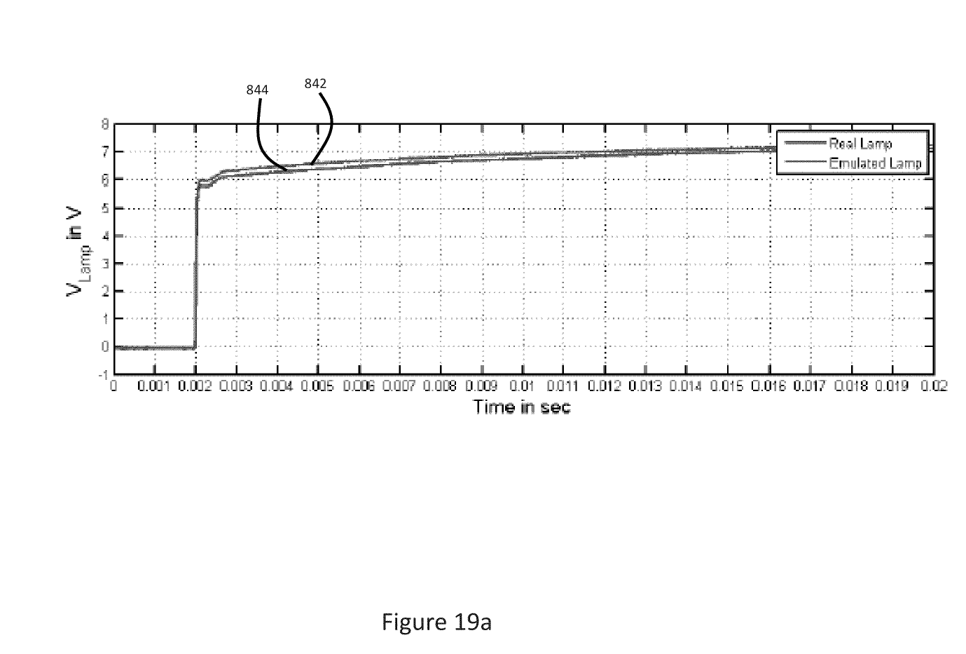

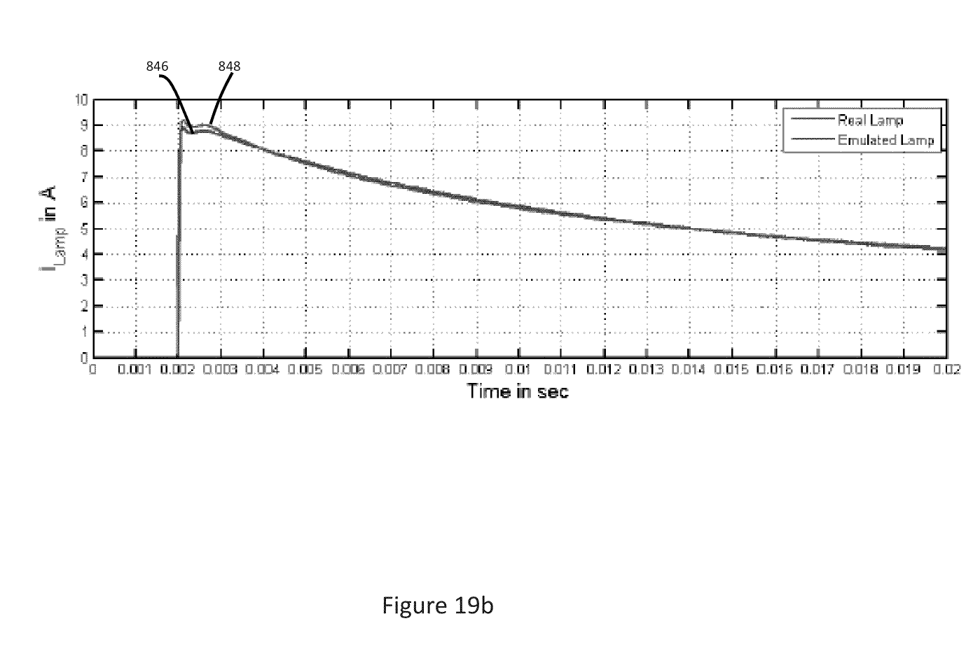

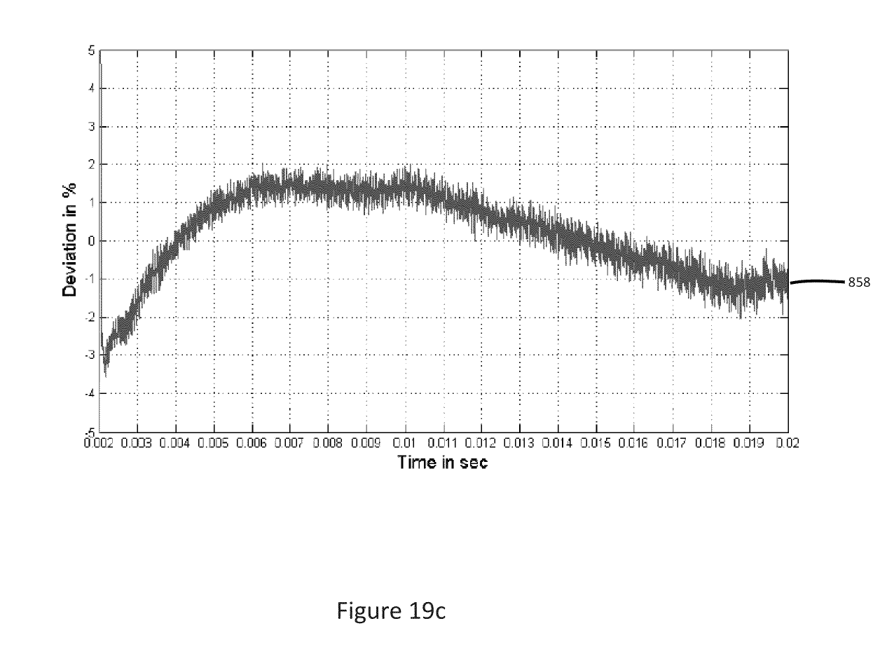

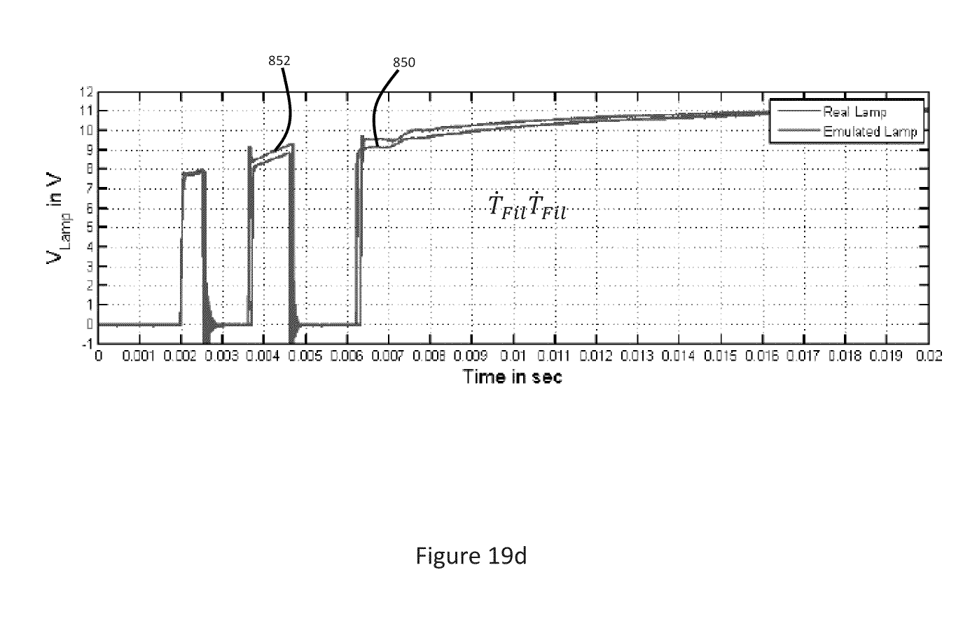

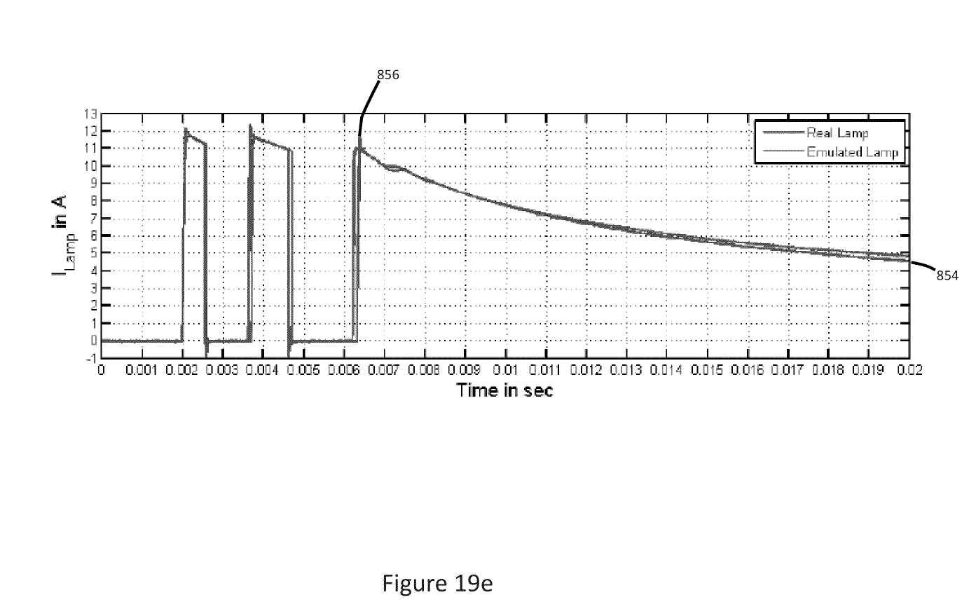

FIGS. 19a-e illustrate current versus time, voltage versus time, and percent deviation versus time responses of an emulated incandescent lightbulb and responses of a real incandescent lightbulb. These figures compare results using an emulated load to results using a real load. FIG. 19a shows the voltage of emulated incandescent lightbulb 842 and the voltage of real incandescent lightbulb 844 verses time in steady state. Similarly, FIG. 19b shows a steady state current verses time graph of real incandescent lightbulb 846 and emulated incandescent lightbulb 848. The steady state response of the emulated incandescent lightbulb is similar to the steady state response of the real incandescent lightbulb. FIG. 19c shows percent deviation of an emulated incandescent lightbulb current from a real incandescent lightbulb current in steady state 858. The relative error does not exceed 5%, with the maximum deviation appearing at the rising slope of the lightbulb's inrush current.

If device under test 104 is a smart power switch, it may have protective features, such as over-current detection, over-voltage detection, and over-temperature shut-down, to protect its circuitry from damage. Incandescent lightbulbs have a high inrush current, often up to ten times their steady state current, due to a low resistance at low temperatures. When current begins to flow, resistance in the filament increases nonlinearly, causing current to decrease nonlinearly. When a smart power switch is coupled to a real incandescent lightbulb, and the lightbulb is turned on, the initial current will often be above the current limit of the switch. The switch may shut down for a certain period of time, when it is automatically switched on again. This toggling is repeated until the current remains below the current limit. FIG. 16d shows a voltage verses time graph of real incandescent lightbulb 850 and emulated incandescent lightbulb 852 undergoing discontinuous toggling, while FIG. 16e shows a current of real incandescent lightbulb 854 and emulated incandescent lightbulb 856 undergoing discontinuous toggling. The response of the emulated incandescent lightbulb is similar to the response of the real incandescent lightbulb with only small deviations. The toggling behavior is important in the testing of smart-high side switches.

Advantages of embodiments include the ability to test device robustness within the variation of active and passive components. In some embodiments, emulators may accurately emulate an apparatus in real time. Additionally, embodiments may be capable of operating at a high power and high currents, for example at a current of 90 A. Also, in some embodiments, emulators may be configurable to emulate multiple devices. Additionally, embodiments may allow the testing of smart power switches undergoing toggling.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of testing a circuit that includes a device under test that is functionally connected to an emulated apparatus, the emulated apparatus comprising digital circuitry that models a real device, the method comprising:
powering the circuit;
digitally calculating a response of the circuit after the powering, the calculated response being determined at least based on the emulated apparatus;
generating an analog response signal based on the calculated response; and
applying the analog response signal to the circuit.

2. The method of claim 1, wherein the device under test comprises a switch.

3. The method of claim 2, wherein the emulated apparatus comprises a load, wherein the circuit comprises the switch coupled between the load and a power source.

4. The method of claim 1, further comprising performing a plurality of iterations by repeating the powering, the digitally calculating, the generating, and the applying steps a number of times, wherein the calculated response is based on an updated emulation model for each iteration.

5. The method of claim 4, wherein the updated emulation model is based on a time-shifted version of the calculated response of a previous iteration.

6. The method of claim 1, wherein the calculating is performed by an FPGA and wherein the analog response signal is applied by a power amplifier.

7. The method of claim 1, wherein the emulated apparatus comprises digital circuitry that models an incandescent lightbulb.

8. The method of claim 1, wherein the emulated apparatus comprises digital circuitry that models a motor.

9. The method of claim 1, wherein the emulated apparatus comprises digital circuitry that models a battery.

10. The method of claim 1, wherein the emulated apparatus comprises digital circuitry that models an LED.

11. A method for emulating an apparatus, the method comprising:
causing a circuit to be closed so that a load unit is coupled to a power source unit, wherein the load unit or the power source unit comprises an emulation model;
digitally determining a response when the circuit is closed based on the emulation model, the digitally determined response including an emulation delay relative to a response that would have occurred if neither the load nor the power source were an emulation model;
updating the emulation model based upon a time-shifted version of the response, the time-shifted version of the response being adjusted in time by an amount of delay less than the emulation delay;
causing the circuit to be closed again so that the load unit is coupled is to the power source unit; and
digitally determining a further response when the circuit is closed again based on the updated emulation model.

12. The method of claim 11, further comprising re-updating the emulation model based upon a time-shifted version of the further response, the time-shifted version of the response being adjusted in time by a further amount of delay.

13. The method of claim 12, further comprising the steps of causing the circuit to be closed again, digitally determining a further response, and re-updating the emulation model based upon a time-shifted version of the further response.

14. The method of claim 13, wherein the time-shifted version of the response adjusted in time by a same amount of delay each time the steps are repeated.

15. The method of claim 13, wherein the time-shifted version of the response adjusted in time by a different amount of delay each time the steps are repeated.

16. The method of claim 15, wherein each further amount of delay is half of an immediately previous amount of delay.

17. The method of claim 11, wherein the load unit comprises the emulation model.

18. The method of claim 11, wherein the power source unit comprises the emulation model.

19. The method of claim 11, wherein both the load unit and the power source unit comprise emulation models.

20. The method of claim 11, wherein updating the emulation model comprises updating a PID controller.

21. The method of claim 11, wherein causing a circuit to be closed comprises closing a switch, the switch being a device under test.

22. The method of claim 21, wherein the switch comprises a smart power switch.

23. The method of claim 11, wherein causing a circuit to be closed comprises successively closing and opening a switch based upon a current flowing through the circuit.

24. A system for testing a device, the system comprising:
an analog-to-digital converter configured to be coupled to a device under test;
a signal processing unit configured to digitally determine a response based on an emulation model of an emulated apparatus, the signal processing unit having an input coupled to an output of the analog-to-digital converter;
a digital-to-analog converter coupled to the signal processing unit, the digital-to-analog converter configured to convert digital signal generated by the signal processing unit into an analog signal; and
a power amplifier coupled to receive the analog signal from the digital-to-analog converter, the power amplifier configured to be coupled to the device under test.

25. The system of claim 24, the signal processing unit further configured to perform a plurality of iterations by repeatedly digitally determining a response based on an updated emulation model for each iteration.

26. The system of claim 25, wherein the updated emulation model is based on a time-shifted version of the digitally determined response of a previous iteration.

27. The system of claim 24, wherein the emulation model of the emulated apparatus comprises an emulation model of a light.

28. The system of claim 24, wherein the signal processing unit comprises an FPGA.
